(19) United States
(12) Patent Application Publication
(10) Pub. No.: US 2006/0177692 A1
(43) Pub. Date: Aug. 10, 2006

(54) Organic light-emitting diodes and display comprising the same

(75) Inventor: Tswen-Hsin Liu, Jhudong Township (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/202,978

(22) Filed: Aug. 12, 2005

(30) Foreign Application Priority Data
Feb. 5, 2005 (TW) 94103958

(51) Int. Cl. H01L 51/50; H05B 33/12

(52) U.S. Cl. 428/690; 428/917; 313/504; 313/506

(57) ABSTRACT

An organic light-emitting diode and a display apparatus. The organic light-emitting diode includes a cathode, an anode, an emitting layer disposed between the cathode and the anode, a doped electron transport layer disposed between the cathode and the emitting layer, and a metallic ion capture layer, disposed between the doped electron transport layer and the emitting layer, for capturing metallic ions diffused from the doped electron transport layer. The display including the organic light-emitting diode.

### BACKGROUND

The present invention relates to an organic electroluminescent device and, more specifically, relates to an organic light-emitting diode and a display comprising the same.

When an external electric field is applied to an organic electroluminescent device, electrons and holes are injected from cathode and anode, respectively, and then recombined to form excitons. Energy is further transported from excitons to luminescent molecules with continuous application of an electric field. Finally, luminescent molecules emit light converted from energy. A common organic electroluminescent device structure comprises an ITO (indium tin oxide) anode, a hole transport layer, an emitting layer, a hole blocking layer, an electron transport layer, and a cathode. A complex organic electroluminescent device, however, may further comprise a hole injection layer disposed between an anode and a hole transport layer or an electron injection layer disposed between a cathode and an electron transport layer to improve injection efficiency of carriers, reducing driving voltage or increasing recombination thereof.

Currently, organic light-emitting diodes are a mainstay of portable electrical products. Several novel techniques such as tandem, top-emitting, or inversion structure, however, may cause increase in operating voltage. To solve the problem, active alkali or alkaline metals, such as Li or Cs, are doped into an electron transport material to form radical anions or charge transfer complexes therein, reducing operating voltage. The conductivity of Li-doped electron transport film may exceed 5 grades more than non-doped, about 3×10⁵ S/cm.

Hosts of doped electron transport material are divided into organic and inorganic materials, organic materials such as Alq₃ or Bphen, and inorganic materials such as MnO₂ or WO₃.

Both organic and inorganic materials may exhibit high conductivity after doping alkali or alkaline metals thereinto. Nevertheless, these high active metals may easily be diffused into the emitting layer due to their extremely small size. Once diffusion of metals occurs, photons in the emitting layer may be violently quenched by metallic ions, resulting in low luminance efficiency. Additionally, diffused metals may further react with organic molecules to form complexes, causing deterioration of luminance and formation of carrier traps, significantly increasing operating voltage.

### SUMMARY

The present invention in one aspect, relates to an organic light-emitting diode comprising a cathode, an anode, an emitting layer disposed between the cathode and the anode, a doped electron transport layer disposed between the cathode and the emitting layer, and a metallic ion capture layer, disposed between the doped electron transport layer and the emitting layer, for capturing metallic ions diffused from the doped electron transport layer.

The present invention, in another aspect, relates to a display comprising the above organic light-emitting diode.

These objectives of the present invention will become apparent to those of ordinary skill in the art after reading the following detailed description of the preferred embodiment that is illustrated in the various figures and drawings.

### BRIEF DESCRIPTION OF THE DRAWINGS

The present invention can be more fully understood by reading the subsequent detailed description and examples with references made to the accompanying drawings, wherein:

FIG. 1 is a cross-sectional of a related organic light-emitting diode.

FIG. 2 is a cross-sectional of an organic light-emitting diode of the present invention.

FIG. 3 is a top-view of a display apparatus of the present invention.

FIG. 4 shows operating voltage-current density curves of organic light-emitting diodes of the present invention.

FIG. 5 shows operating voltage-brightness curves of organic light-emitting diodes of the present invention.

### DETAILED DESCRIPTION

The present invention provides an organic light-emitting diode comprising a cathode, an anode, an emitting layer disposed between the cathode and the anode, a doped electron transport layer disposed between the cathode and the emitting layer, and a metallic ion capture layer, disposed between the doped electron transport layer and the emitting layer, for capturing metallic ions diffused from the doped electron transport layer.

The cathode or/and anode should be a transparent electrode, that is, the cathode and the anode may have substantially made from the same materials or substantially made from different materials, and they may comprise metal, metal alloy, transparent metal oxide, or multi-layer thereof. The metal comprises Al, Ca, Ag, Ni, Cr, Ti, or Mg. The metal alloy comprises Mg—Ag alloy or other alloy. The transparent metal oxide comprises ITO, IZO (indium zinc oxide), CTO (cadmium tin oxide), metallized AZO, ZnO (zinc oxide), InN (indium nitride), or SnO₂ (stannum dioxide).

The emitting layer comprises fluorescent materials or phosphorescent materials. The thickness of the emitting layer can be substantially in a range of about 50 Å to about 2000 Å. The doped electron transport layer comprises alkali-doped organic materials, alkaline-doped organic materials, alkali-doped inorganic materials, or alkaline-doped organic materials. The alkali-doped inorganic materials or alkaline-doped organic materials may comprise Li-doped MnO₂. The metallic ion capture layer may comprise organic materials or inorganic materials capable of chelating with metallic ions, such as 4,7-Diphenyl-1,10-phenanthroline (BPhen), 2,9-Dimethyl-4,7-diphenyl-1,10-phenanthroline (BCP), or other phenanthroline derivatives. The thickness of the metallic ion capture layer can be substantially in a range of about 10 Å to about 500 Å, and captures metallic ions diffused from the doped electron transport layer, such as alkali ions or alkaline ions. Materials of the metallic ion capture layer are not limited to the foregoing compounds. All compounds capable of chelating with metallic ions are suitable for used in the present invention, preferably compounds with lone pair electrons and bulky groups, such as phenyl. Lone pair electrons may form hybrid orbits with metallic ions and bulky groups may surround metallic ions. Such structural features can improve chelating effect.

The feature of the present invention is disclosed as follows by the example of chelating of BPhen and Li.

A BPhen molecule comprises two nitrogen atoms with lone pair electrons and two bulky phenyl groups. Li can be captured by BPhen due to its specific chemical structure. For example, if the metallic ion capture layer containing BPhen is disposed between the doped electron transport layer and the emitting layer, metallic ions diffused from the doped electron transport layer may be captured by BPhen before achieving the emitting layer and surrounded by two bulky phenyl groups. Thus, quenching of photons in the emitting layer is effectively terminated, increasing luminance efficiency. Additionally, operating voltage may also be reduced due to the absence of charge carrier traps.

The organic light-emitting diode provided by the present invention further comprises a hole injection layer or a hole transport layer disposed between the anode and the emitting layer, and an electron injection layer disposed between the cathode and the emitting layer. The hole injection layer comprises polymers containing F, C, and H, porphyrin derivatives, or p-doped amine derivatives. The porphyrin derivatives may comprise metallophthalocyanine derivatives, such as copper phthalocyanine.

The hole transport layer comprises amine derivatives, such as N,N′-bis(1-naphyl)-N,N′-diphenyl-1,1′-biphenyl-4,4′-diamine (NPB), N,N′-diphenyl-N,N′-bis(3-methylphenyl)-(1,1′-biphenyl)-4,4′-diamine (TPD), 2T-NATA, or other derivatives. The thickness of the hole transport layer can be substantially in a range of about 50 Å to about 500 Å.

The electron injection layer may comprise alkali halide, alkaline halide, alkali oxide, or metal carbonate, such as LiF, CsF, NaF, CaF₂, Li₂O, CS₂O, Na₂O, Li₂CO₃, CS₂CO₃, or Na₂CO₃. The thickness of the electron injection layer can be substantially in a range of about 5 Å to about 50 Å.

The present invention also provides a display comprising the disclosed organic light-emitting diode. The display may comprise a drive circuit coupled to and driving the organic light-emitting diode. The drive circuit comprises a thin film transistor.

Referring to FIG. 2, an organic light-emitting diode provided by the present invention is disclosed. The organic light-emitting diode 10 comprises an anode 12, a hole injection layer 14, a hole transport layer 16, an emitting layer 18, a metallic ion capture layer 20, a doped electron transport layer 22, an electron injection layer 24, and a cathode 26, wherein the metallic ion capture layer 20 may capture metallic ions diffused from the doped electron transport layer 22.

Referring to FIG. 2, a method of fabricating an organic light-emitting diode is also provided. First, an anode 12 is provided. Next, a hole injection layer 14, a hole transport layer 16, an emitting layer 18, a metallic ion capture layer 20, a doped electron transport layer 22, an electron injection layer 24, and a cathode 26 are evaporated on the anode 12 in order. Finally, the diode is packaged to form an organic light-emitting device.

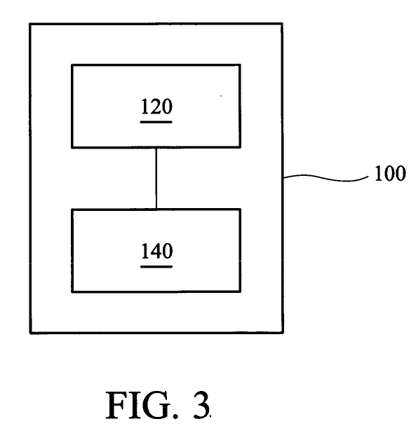

Referring to FIG. 3, a display provided by the present invention is disclosed. The display 100 comprises an organic light-emitting diode 120 and a drive circuit 140 coupled to the organic light-emitting diode 120 to drive the organic light-emitting diode 120.

The display may comprise a computer monitor, flat panel display (FPD), cell phone, hand-held videogame, digital camera (DC), digital video (DV), digital broadcast system, personal digital assistant (PDA), notebook, or table PC.

### EXAMPLES

### Comparative Example 1

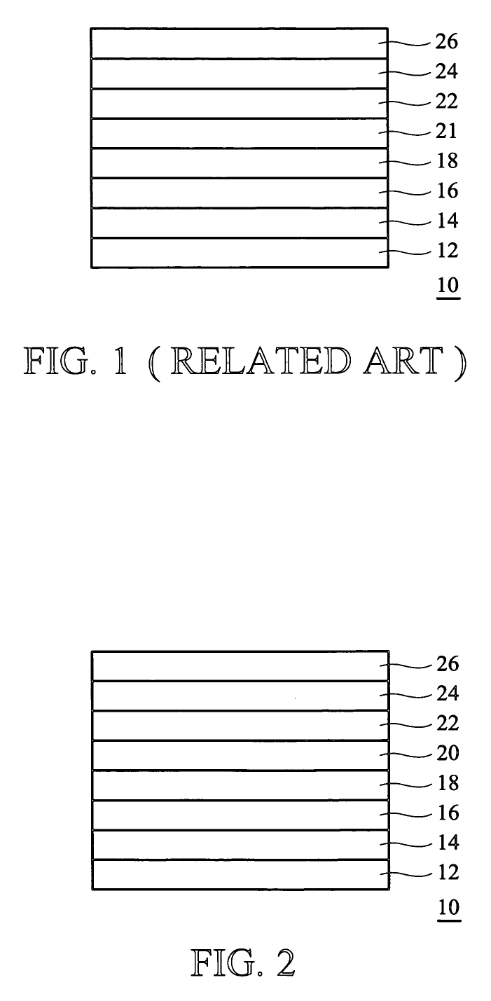

Referring to FIG. 1, a method of fabricating an organic light-emitting diode (device A) is disclosed as follows. An ITO anode 12 was provided on a substrate and treated with O₃. Copper phthalocyanine was evaporated on the ITO anode 12 to form a hole injection layer 14. NPB was evaporated on the hole injection layer 14 to form a hole transport layer 16. Alq₃ and C-545T were co-evaporated on the hole transport layer 16 to form an emitting layer 18, and a BAlq layer or a material layer 21 lack of metal ions capture capability was evaporated thereon. MnO₂ and Li were co-evaporated on the BAlq layer 21 to form a doped electron transport layer 22. LiF was evaporated on the electron transport layer 22 to form an electron injection layer 24. Finally, Al was evaporated on the electron injection layer 24 to form a cathode 26.

### Example 1

Referring to FIG. 2, a method of fabricating an organic light-emitting diode (device B) of the present invention is provided. First, an ITO anode 12 was provided on a substrate and treated with O₃. Copper phthalocyanine was evaporated on the ITO anode 12 to form a hole injection layer 14. NPB was evaporated on the hole injection layer 14 to form a hole transport layer 16. Alq₃ and C-545T were co-evaporated on the hole transport layer 16 to form an emitting layer 18. BPhen was evaporated on the emitting layer 18 to form a metallic ion capture layer 20. MnO and Li were co-evaporated on the metallic ion capture layer 20 to form a doped electron transport layer 22, and LiF was evaporated thereon to form an electron injection layer 24. Finally, Al was evaporated on the electron injection layer 24 to form a cathode 26.

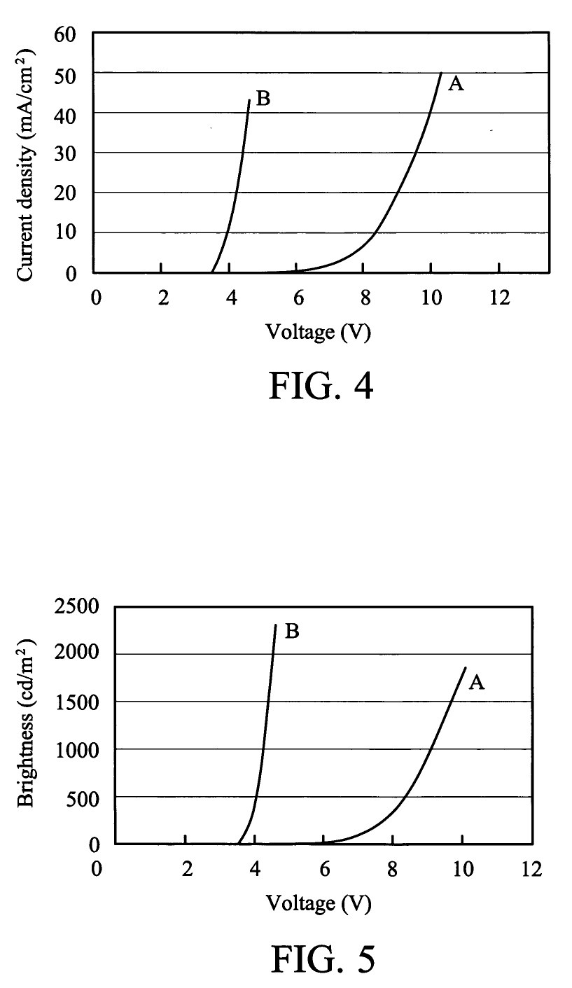

Referring to FIG. 4, if current density of 20 mA/cm² is required, device A provides 9V operating voltage. Device B, however, merely requires 4V operating voltage, saving 5V. The metallic ion capture layer containing BPhen capable of chelating with metallic ions disposed between the doped electron transport layer and the emitting layer thus provides high electron injection capability, significantly reducing operating voltage.

Referring to FIG. 5, if brightness of 1000 cd/m² is required, device A needs to provide 9V operating voltage. Device B, however, merely requires 4V operating voltage, also saving 5V. This shows the device B provided by the present invention also exhibits high luminance efficiency.

While the present invention has been described by way of example and in terms of preferred embodiment, it is to be understood that the present invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An organic light-emitting diode, comprising:
a cathode and an anode;
an emitting layer disposed between the cathode and the anode;
a doped electron transport layer disposed between the cathode and the emitting layer; and
a metallic ion capture layer, disposed between the doped electron transport layer and the emitting layer, for capturing metallic ions diffused from the doped electron transport layer.

2. The organic light-emitting diode of claim 1, wherein at least one of the cathode and the anode comprises a transparent electrode.

3. The organic light-emitting diode of claim 2, wherein the cathode and the anode comprises metal, metal alloy, transparent metal oxide, or multi-layer thereof.

4. The organic light-emitting diode of claim 2, wherein the cathode and the anode are substantially made of the same material.

5. The organic light-emitting diode of claim 2, wherein the cathode and the anode are substantially made of different materials

6. The organic light-emitting diode of claim 1, wherein the emitting layer comprises phosphorescent material or fluorescent material.

7. The organic light-emitting diode of claim 1, wherein the doped electron transport layer comprises alkali-doped organic material or alkaline-doped organic material.

8. The organic light-emitting diode of claim 1, wherein the doped electron transport layer comprises alkali-doped inorganic material or alkaline-doped inorganic material.

9. The organic light-emitting diode of claim 1, wherein the metallic ion capture layer comprises organic material or inorganic material capable of chelating with metallic ions.

10. The organic light-emitting diode of claim 1, wherein the metallic ion capture layer comprises a phenanthroline derivative.

11. The organic light-emitting diode of claim 10, wherein the phenanthroline derivative comprises 4,7-Diphenyl-1,10-phenanthroline (BPhen) or 2,9-Dimethyl-4,7-diphenyl-1,10-phenanthroline (BCP).

12. The organic light-emitting diode of claim 1, further comprising at least one of a hole injection layer and a hole transport layer disposed between the anode and the emitting layer.

13. The organic light-emitting diode of claim 12, wherein the hole injection layer comprises polymers containing F, C, and H, porphyrin derivatives, or p-doped amine derivatives.

14. The organic light-emitting diode of claim 12, wherein the hole transport layer comprises amine derivatives.

15. A display comprising an organic light-emitting diode of claim 1.
